(19) United States
(12) Patent Application Publication
(10) Pub. No.: US 2007/0145346 A1
(43) Pub. Date: Jun. 28, 2007

(54) Connection electrode for phase change material, associated phase change memory element, and associated production process

(76) Inventor: Harald Seidl, Poring (DE)

Correspondence Address: BRINKS HOFER GILSON & LIONE;INFINEON, PO BOX 10395, CHICAGO, IL, 60610, US

(21) Appl. No.: 11/390,560

(22) Filed: Mar. 28, 2006

(30) Foreign Application Priority Data
Mar. 31, 2005 (DE) 10 2005 014 645.7

(51) Int. Cl. H01L 29/04

(52) U.S. Cl. 257/3

(57) ABSTRACT

The present disclosure relates to a connection electrode for phase change materials, to an associated phase change memory element and to an associated production process, wherein a plurality of separate insulation regions are formed in an electrode material at least at a connection surface. This reduces the overall size of the contact surface, with the result that even with high integration densities, the necessary Joule heating, and therefore programming, at very low currents can be realized.

### RELATED APPLICATIONS

The present patent document claims priority to German Application Serial No. DE 10 2005 014 645.7, filed Mar. 31, 2005, the entirety of which is hereby incorporated by reference.

### BACKGROUND

The present disclosure relates to a connection electrode for phase change materials, to an associated phase change memory element and to an associated production process, and in particular to connection electrodes which allow particularly high integration densities to be achieved with memory circuits of this type.

What are known as phase change memory elements use materials whose electrical properties can be reversibly switched from one phase to another. By way of example, materials of this type change between an amorphous phase and a crystalline or polycrystalline phase. In particular a resistance or conductance of a material of this type is very different in these two different phase states.

Therefore, phase change memory elements usually use phase change materials which, for example, represent alloys of elements from group VI of the periodic system and are known as chalcogenides or chalcogenide materials. Accordingly, in the text which follows, phase change materials of this type are to be understood as meaning materials which can be switched between two different phase states with different electrical properties (resistances).

Currently the most widespread chalcogenides or phase change materials consist of an alloy of Ge, Sb and Te (GeₓSb_{y}Te_{z}). Ge₂Sb₂Te₅ is already used in a large number of phase change memory elements and is also known as a material for rewritable optical storage media (e.g. CDs, DVDs etc.).

The changes in the resistance of phase change materials are utilized in order, for example, to create nonvolatile memory elements (NVM) and to store information. Accordingly, materials of this type have a higher resistance in the amorphous phase than in the crystalline or polycrystalline phase. Accordingly, a phase change material can be used as a programmable resistor, the resistance of which can be reversibly altered as a function of its phase state.

An overview of phase change materials of this type is known, for example, from literature reference S. Hatkins et al.: “Overview of phase-change chalcogenide nonvolatile memory technology”, MRS Bulletin/November 2004, pages 829 to 832.

A change in the phase of materials of this type can be caused by a local increase in a temperature. Both phase states are usually stable below 150 degrees Celsius. Above 300 degrees Celsius, rapid crystal nucleation takes place, resulting in a change in the phase state to a crystalline or polycrystalline state, provided that a temperature of this nature is present for a sufficient length of time. To return the phase state to the amorphous state, the temperature is increased to above the melting point of approx. 600 degrees Celsius, followed by very rapid cooling. Both critical temperatures, i.e. both for the crystallization and for the melting, can be generated using an electric current which flows through an electrically conductive connection electrode with a predetermined resistance and is in contact with or in the vicinity of the phase change material. The heating is in this case carried out by what is known as Joule heating.

FIG. 1 shows a simplified sectional view through a phase change memory element according to the prior art, in which a semiconductor switching element, such as for example a field-effect transistor having a source region S, a drain region D and a gate G, which is located above a gate dielectric GD, is formed in a semiconductor substrate 10. The source region S is connected, for example by a connection element 30, to a connection electrode 40, which contact-connects the phase change material 50 having the properties described above. A further connection counterelectrode 60, which is electrically connected to an interconnect 80 via a further connection element 70, is provided on the opposite main surface of the phase change material 50. Furthermore, the drain region D can likewise be connected to an interconnect 100 via a connection element 90.

Reference numeral 20 denotes an insulating interlayer dielectric. The section of the phase change material 50 which is in direct contact with the connection electrodes 40 and 60 defines the effective phase change region of the chalcogenide material.

If an electric current at a sufficiently high level is now passed through the connection electrode 40, this phase change section of the phase change material 50 can undergo a corresponding crystallization heating or melting heating, thereby causing a phase change. In this case, only a short time (short current pulse) but a high temperature (high current level) are required to render the phase change material amorphous, whereas a lower current has to be applied for a longer time to render it crystalline.

The phase state which has been set can be read by applying a sufficiently low read voltage which does not cause critical heating. Since the measured current is proportional to the conductivity or resistance of the phase change material, the phase states which have been set in this manner can be reliably recorded. Since, furthermore, the phase change material can be electrically switched almost any desired number of times, it is very easy to produce nonvolatile memory elements.

To avoid interference between adjacent memory elements, in accordance with FIG. 1 phase change storage elements are usually realized with a selection element, such as for example the field-effect transistor illustrated. However, this selection element may equally also be a bipolar transistor (not shown), a diode or some other form of switching element.

However, a drawback of memory elements of this type is formed by the very high programming currents which are required to change the phase state. In particular in semiconductor circuits with very high integration densities, however, currents of this level are subject to considerable restrictions; for example, in the case of gate lengths of approx. 100 nm and a gate dielectric which resists a voltage of 3 V, maximum currents of 100 to 200 μA are available. This results in contact surfaces with respect to the phase change material of at most 20 nm×20 nm, which are much smaller than structures which can be realized by lithographic means.

To achieve such high current densities or small contact surfaces, U.S. Pat. No. 6,746,892 B2 has disclosed, for example, the use of connection electrodes which have a tapered shape.

Furthermore, US 2003/0209746 A1 has disclosed a connection electrode in which a lithographically patterned connection surface for a phase change material is reduced in size by spacers, in such a manner that in turn a very small contact surface and in particular a sublithographic contact surface between the connection electrode and the phase change material can be realized.

However, this does not allow accurate setting of the contact surface which is actually active between the connection electrode and the phase change material.

### BRIEF SUMMARY

Therefore, the disclosure is based on the object of providing a connection electrode for phase change materials, an associated phase change memory element and an associated production process with which an effective contact surface and therefore a spatial delimitation of the current path can be set with a high level of accuracy.

Accordingly, in accordance with the disclosure an electrode material of the connection electrode has a multiplicity of insulation regions which are formed at least at the connection surface to the phase change material.

In this case, the electrode material is preferably lithographically patterned, whereas the insulation regions are formed at a sublithographic level.

The insulation regions in this case preferably have a grain-like surface cross section and consist of SiO₂, while the electrode material includes TiN.

With regard to the phase change memory element, the connection electrode is preferably formed in a contact hole of a dielectric, with the phase change material being formed either at the surface of the dielectric outside the contact hole or only at the surface of the connection electrode within the contact hole.

With regard to the process for producing a phase change memory element, it is preferable for a multiplicity of masking elements to be formed at the surface of an auxiliary dielectric, then in a subsequent step, regions of the auxiliary dielectric which are not covered by the masking elements are etched back anisotropically to form a multiplicity of insulation regions, and the resulting uncovered regions are filled with an electrode material to form a connection electrode.

It is preferable for the masking elements to be formed at a sublithographic level, in which case in particular what are known as LPCVD processes are used to produce semiconductor nanocrystals or HSG processes are used to produce HSG grains (hemispherical silicon grains).

In particular TiN is deposited conformally over the entire surface by means of an ALD process as the electrode material and is removed from a common surface of the dielectric and the insulation regions.

Alternatively, it is also possible for the connection electrode to be etched back to a predetermined depth in the contact hole and for the phase change material to be formed only in this recess, resulting in a self-aligning process with a maximum integration density.

### BRIEF DESCRIPTION OF THE DRAWINGS

The disclosure is described in more detail below on the basis of exemplary embodiments and with reference to the drawing, in which:

FIG. 1 shows a simplified sectional view of a phase change memory element in accordance with the prior art;

FIGS. 2A to 2G show simplified section views and a plan view illustrating significant production steps involved in the realization of a phase change memory element with a connection electrode in accordance with a first exemplary embodiment of the disclosure; and

FIG. 3 shows a simplified sectional view illustrating a phase change memory element with a connection electrode in accordance with a second exemplary embodiment of the disclosure.

### DETAILED DESCRIPTION OF THE DRAWINGS

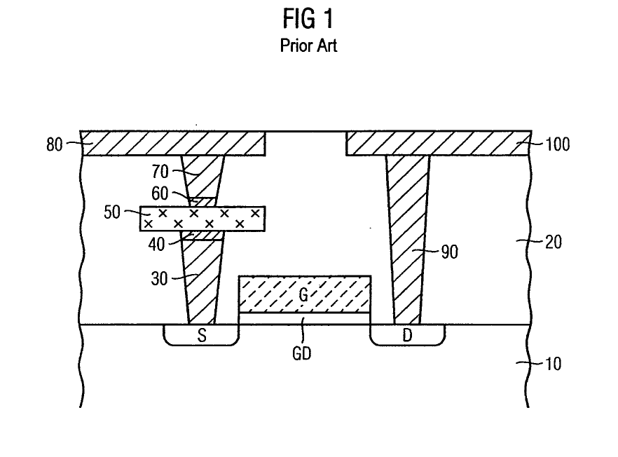

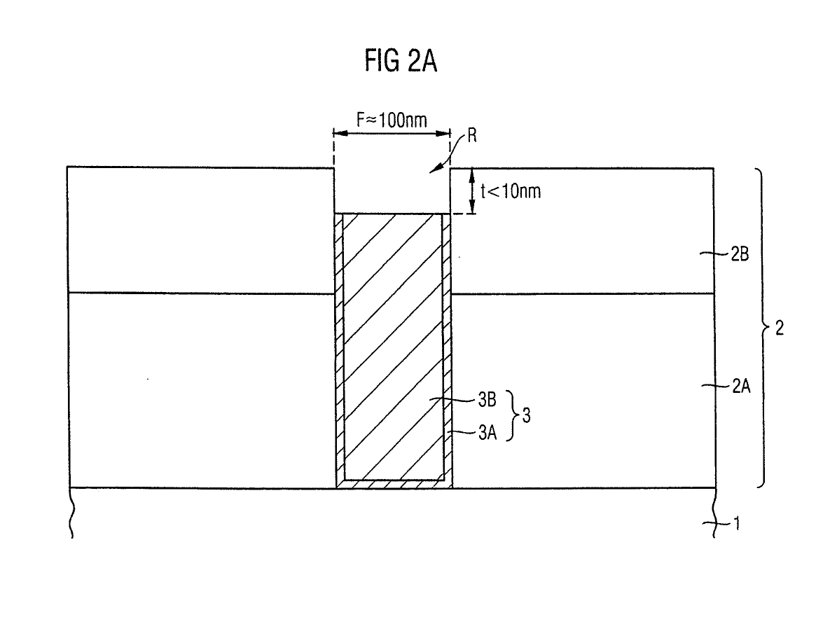

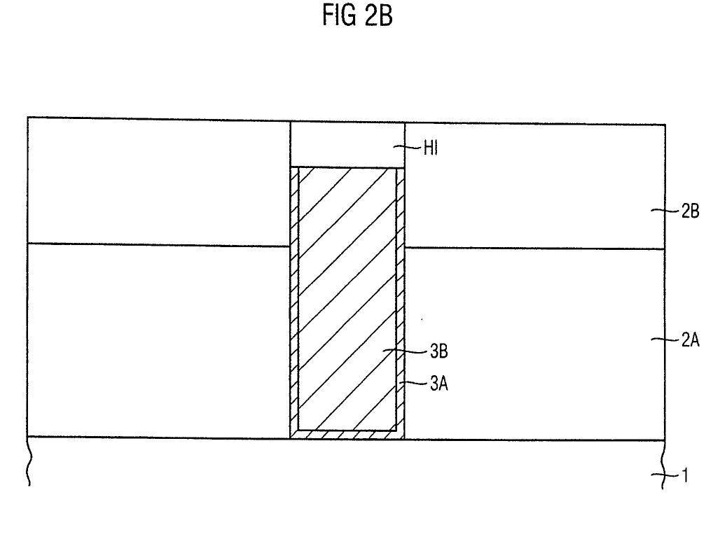

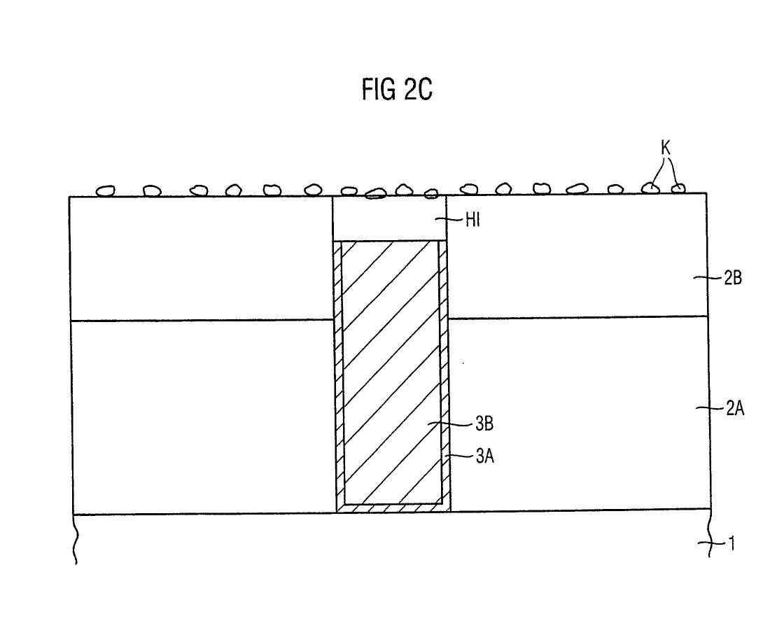

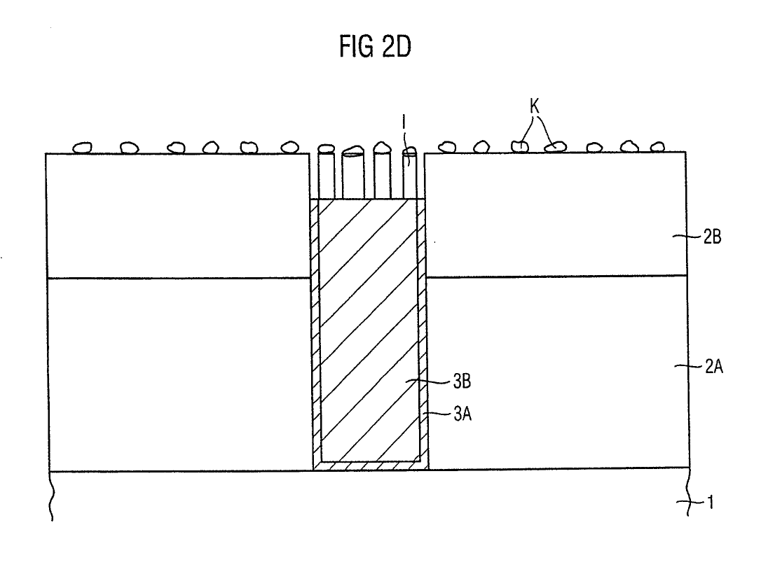

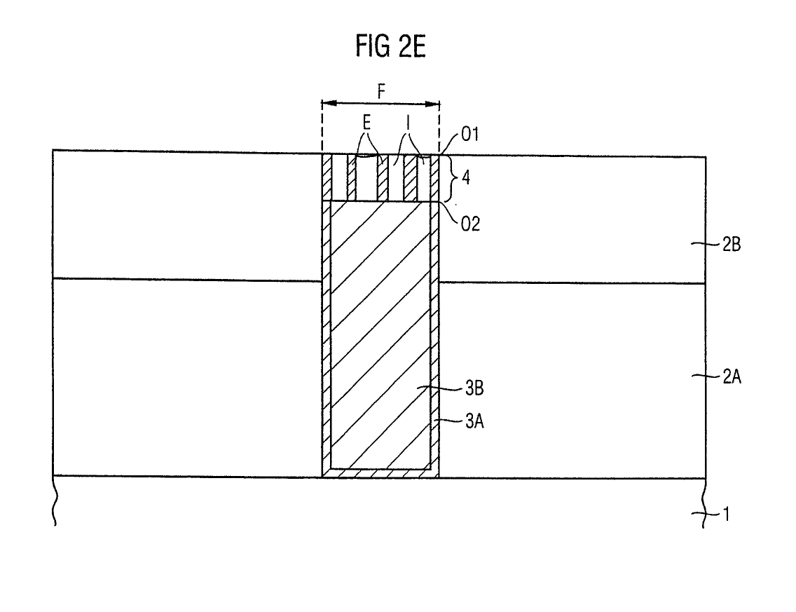

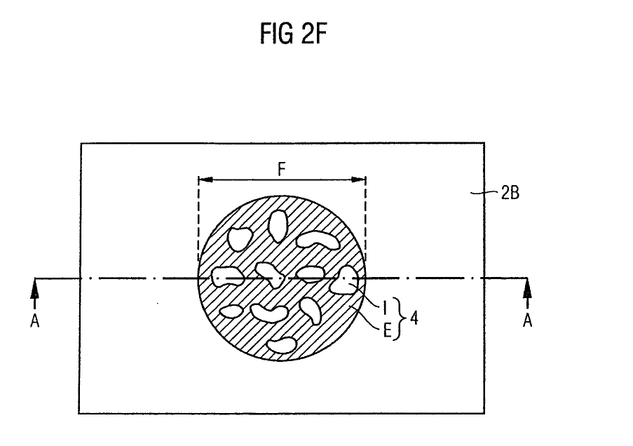

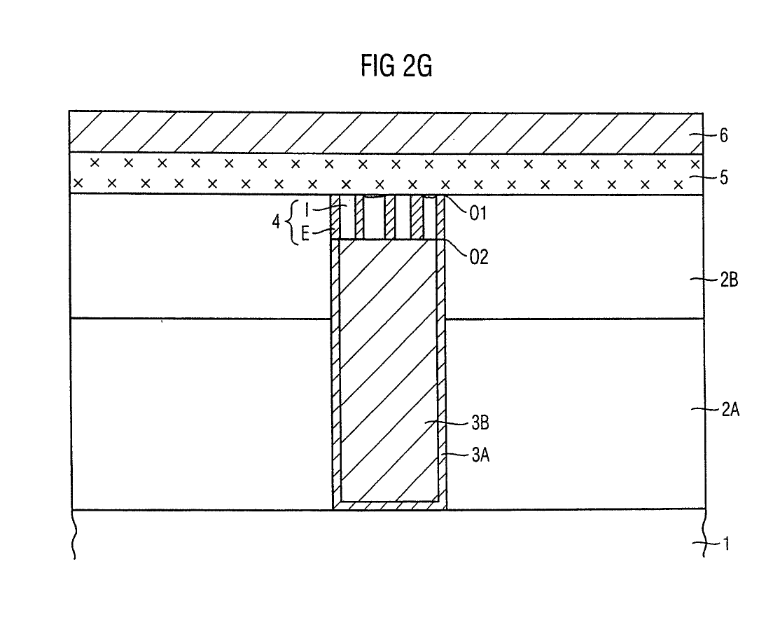

FIGS. 2A to 2G show simplified sectional views and a plan view illustrating a process for producing a connection electrode for phase change materials, and in particular for a phase change memory element, as can be used for example in a phase change memory cell as shown in FIG. 1.

In accordance with FIG. 2A, first of all a dielectric 2 is formed on a carrier layer 1, the carrier layer 1 preferably including a single-crystal Si semiconductor substrate and the dielectric 2 having a multilayer structure. More specifically, by way of example, an SiO₂ layer is deposited or formed thermally at the surface of the carrier layer 1 or the Si semiconductor substrate, as first insulation layer 2A, and then a second insulation layer 2B, consisting for example of Si₃N₄, is deposited over the entire surface of the first insulation layer 2A. The advantage of this double layer is that the second insulation layer 2B can be used as an etching stop layer in a subsequent process step.

In principle, it is also possible to use other insulation layers and in particular alternative interlayer dielectrics as dielectric 2. In the same way, the carrier layer 1 may also form a metallization level or another, preferably electrically conductive layer.

To realize an electrical connection to a selection element formed in the semiconductor material, such as for example the source region S as shown in FIG. 1, a contact hole in the dielectric 2 or the first and second insulation layers 2A and 2B is then formed by means of conventional lithographic processes. The contact hole preferably has a size F, where F denotes a minimum feature size that can be realized by lithography. The contact hole may, for example, have a rectangular, square, circular or oval shape. Standard etching processes are customarily used to form this contact hole, and consequently no further detailed description is given below.

In accordance with FIG. 2A, a connection element 3 is now formed within this contact hole or the opening in the dielectric 2. By way of example, a thin liner layer is deposited at the surface of the contact hole or the opening, i.e. at the side faces of the insulation layers 2A and 2B and the base region, and this liner layer is then thermally annealed. It is preferable for a Ti/TiN double liner layer with a layer thickness of 10 nm/10 nm to be deposited with a uniform layer thickness, i.e. conformally, and annealed at a predetermined temperature, resulting in a reliable barrier layer preventing outdiffusion of impurities into the semiconductor material or the carrier layer 1.

This liner deposition is followed by filling of the opening or contact hole with an electrically conductive filling layer 3B, which preferably involves tungsten being deposited over the entire surface and then etched back to a predetermined depth (e.g. 10 nm) into the opening or contact hole. An etchback of this type can be carried out, for example, by means of a dry etching process, and in particular by means of reactive ion etching (RIE). Furthermore, it is also possible for the liner layer 3A at the side walls of the contact hole to be removed in this upper section, resulting in the recess R in the contact hole or opening as illustrated in FIG. 2A. It is preferable for an isotropic and in particular a wet-chemical etching process to be employed for the removal of the liner layer 3A. In principle, however, it is also possible to carry out dry-chemical and/or directional etching processes. In principle, the recess R may also have a dimension which differs from that of the contact hole, in which case, to realize the required high current densities, it preferably has a minimum feature size F that can be realized by means of lithographic processes.

Then, as shown in FIG. 2B, an auxiliary dielectric HI is introduced into the recess R. This preferably involves depositing SiO₂ over the entire surface by means of a CVD (chemical vapor deposition) process and then planarizing it down to the surface of the dielectric 2 or the second insulation layer 2B. Therefore, with a typical depth of the recess R of approx. 10 nm, an SiO₂ layer which is at least 10 nm thick is deposited and planarized. With the current minimum feature sizes that can be produced by lithography of F=100 nm, therefore, an aspect ratio of 1:10 results for the recess R.

Then, as shown in FIG. 2C, a multiplicity of masking elements K, which are spaced apart from one another, are formed at least at the surface of the auxiliary dielectric HI. It is preferable for these separated masking elements K to be formed at a sublithographic level or for their feature sizes to have sublithographic dimensions, and therefore they should have a feature size of from 1 to 15 nm. By way of example, what is known as the HSG (Hemispherical Silicon Grain) process, in which silicon grains of a size of from 5 to 15 nm are formed over the entire surface of the dielectric 2 and the auxiliary dielectric HI, is known for the production of masking elements K of this type. Although this process for increasing the surface area of storage capacitors, which is known in particular from the fabrication of DRAMs, can already produce very useable masking elements K, it is preferable for what is known as an LPCVD process subsequently to be used to produce Si nanocrystals. A process of this type is known, for example, from literature reference De Salvo et al.: “How far will Silicon nanocrystals push the scaling limits of NVMs technologies?” IEDM 2003.

This process can be used to produce nanocrystals or what are known as nanodots as masking elements K with a feature size of from 1 nm to 10 nm. In this case, in addition to the size of these nanodots or masking elements K, it is also possible for a surface density to be very accurately set or varied, which is important for the precise setting of a connection electrode surface area that is ultimately effective. It is preferable for the size of the nanodots or masking elements K to be at least one order of magnitude smaller than a feature size of the opening or contact hole, i.e. the masking elements K in grain form have a feature size of less than 1/10 F.

Then, in accordance with FIG. 2D, that region of the auxiliary dielectric HI which is not covered by the masking element K can be anisotropically etched back as far as the connection element 3 of the filling layer 3B and the liner layer 3A. In this way, a multiplicity of insulation regions I which are separate from one another, as it were in “island” form are produced. On account of the use of the Si₃O₄ insulation layer 2B, a targeted etchback of the auxiliary dielectric HI, which preferably consists of SiO₂, can be carried out using standard etching processes which are selected with respect to the material of the masking elements K, i.e. with respect to the silicon and with respect to the material of the second insulation layer 2B. In principle, it is also possible to carry out a non-directional or only partially directional etch, so that the shape of the insulation regions can be influenced.

In accordance with FIG. 2E, in a subsequent step the masking elements K (nanodots or HSG grains) located at the surface can be removed selectively with respect to the auxiliary dielectric HI, with respect to the connection element 3 and with respect to the second insulation layer 2B or the dielectric 2. In principle, CMP (Chemical Mechanical Polishing) processes can be carried out in addition to wet-chemical etching processes of this type.

Furthermore, in accordance with FIG. 2E, a space between the insulation regions I, which has been uncovered by the for example anisotropic etchback, is then filled with an electrode material E to form a connection electrode 4. TiN as electrode material E can preferably be deposited over the entire surface conformally and in particular by means of an ALD (Atomic Layer Deposition) process and can finally be removed from the common surface of the dielectric 2 and the insulation regions I. This removal is preferably effected by means of a planarization process, such as for example a CMP process. Once again, only selectivity with respect to the second insulation layer 2B and the material of the insulation regions I is required.

FIG. 2F shows a simplified plan view of the connection electrode 4 as is present following the production step illustrated in FIG. 2E. Accordingly, the connection electrode 4 includes an electrode material E, the basic shape of which is preferably defined lithographically by the contact hole and in which a multiplicity of insulation regions I are formed or incorporated at least at the connection surface to a phase change material. The insulation regions I, which are preferably formed at a sublithographic level, therefore produce a multiplicity of preferably separate islands in a “sea” of the electrode material E. On account of the sublithographic processes used, and in particular the HSG process and the LPCVD-Si nanocrystal process, the insulation regions I have a grain-like structure that is characteristic of these production processes at the connection surface. By contrast, as shown in FIG. 2E, the insulation regions, in cross section with respect to the connection surface, have a cylindrical structure which substantially results from the directional etching process.

Although, in accordance with FIGS. 2E and 2F, the insulation regions I extend from the connection surface O1 to an opposite main surface O2, and are consequently in “island” form, they may also be formed only at the connection surface O1 and therefore “float” on the electrode material E. An embodiment of this type may result, for example, when using an isotropic or partially isotropic etching process, in which insulation material remains in place only directly beneath the masking grains K but is otherwise removed. In principle, it is also possible for all of the insulation regions I or just some of them to touch one another, resulting in a “network” structure of the insulation regions I.

In accordance with FIG. 2G, a phase change material 5 is then formed at least at the surface of the connection electrode 4. In accordance with the first exemplary embodiment, it is preferable for GeₓSb_{y}Te_{z} to be deposited over the entire surface, for example by means of a PVD or CVD process, although ALD (Atomic Layer Deposition) processes may also be used. Finally, a connection counterelectrode 6 is formed at the main surface of the phase change material 5 which lies on the opposite side from the connection electrode 4. In this case, it is preferable for TiN to be deposited over the entire surface, once again by means of a PVD, CVD or ALD process.

A nonvolatile memory cell of this type is then completed in the same way as in the prior art, for example as illustrated in FIG. 1.

The result is a connection electrode 4 and an associated phase change memory element and an associated production process, in which the switching current required can be very accurately reduced and set by the spatial delimiting of the current path, with the result that even with high integration densities the required Joul heating can be realized using very low current intensities.

The variation in the connection electrode cross-sectional area can be set very accurately, in particular when using LPCVD Si nanocrystal processes, by varying the size and density of the nanodots. On account of the random distribution of the nanodots, the result is a very uniform distribution of the flow of current over the contact surface of the connection electrode, resulting in a very high scalability of the process irrespective of the lithography and the nanodot sizes used.

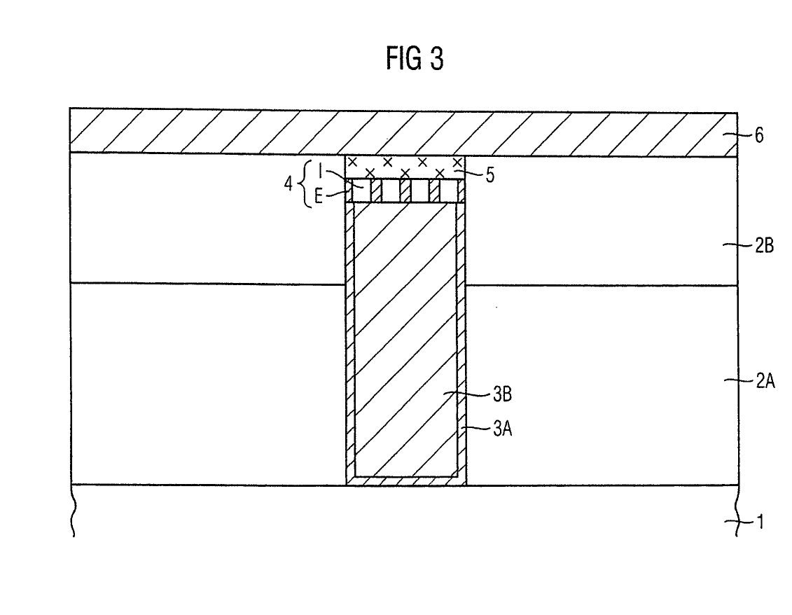

FIG. 3 shows a simplified sectional view of a phase change memory element in accordance with a second exemplary embodiment; identical reference designations denote identical or similar layers and elements to those illustrated in FIGS. 2A to 2G, and consequently these layers and elements will not be described again.

In accordance with this second exemplary embodiment, following a step as shown in FIG. 2E, an upper section of the connection electrode 4 is removed, or the SiO₂ insulation regions I and the TiN electrode material E are etched back into the contact hole to a predetermined depth, which corresponds to approximately half the height of the original connection electrode. Then, a phase change material 5, in particular GeₓSb_{y}Te_{z}, is deposited over the entire surface, once again by means of an ALD, CVD, PVD process, and is then planarized as far as the surface of the dielectric 2 or of the second insulation layer 2B.

Finally, as in the first exemplary embodiment shown in FIG. 2G, a connection counterelectrode 6, preferably formed from TiN, is deposited over the entire surface. The thickness of the phase change material 5 in accordance with FIG. 3 should typically be ≧10 nm, in which case the connection electrode 4 likewise has a thickness of approx. 10 nm. It is then in turn possible to complete a phase change memory cell using the standard processes, for example as shown in FIG. 1.

The disclosure has been described above on the basis of GeₓSb_{y}Te_{z} as phase change material. However, it is not restricted to this particular compound, and equally also encompasses alternative phase change materials.

In the same way, the further materials are not restricted to the materials described above, but rather may also encompass alternative materials. In particular, the dielectric 2 does not have to have a multilayer structure.

Furthermore, the disclosure is not restricted to an Si semiconductor substrate as carrier layer 1, but rather in the same way may also be formed on other carrier layers and in particular in wiring layers located above.

It is therefore intended that the foregoing detailed description be regarded as illustrative rather than limiting, and that it be understood that it is the following claims, including all equivalents, that are intended to define the spirit and scope of this disclosure.

1. A connection electrode for phase change material comprising:
an electrically conductive electrode material comprising at least one connection surface; and
a plurality of insulation regions formed within the electrically conductive electrode material;
wherein at least a portion of the plurality of insulation regions are formed at least partially at the at least one connection surface of the electrically conductive electrode material to reduce an overall size of the at least one connection surface.

2. The connection electrode of claim 1, wherein the plurality of insulation regions are sublithographically patterned, and the electrically conductive electrode material is formed cohesively between at least two of the plurality of insulation regions.

3. The connection electrode of claim 1, wherein at least one of the plurality of insulation regions extends from one of the at least one connection surface of the electrically conductive electrode material to an opposite main surface of the electrically conductive electrode material.

4. The connection electrode of claim 1, where at least one of the plurality of insulation regions comprises a grain-like structure at the connection surface of the electrically conductive electrode material.

5. The connection electrode of claim 4, wherein at least one of the plurality of insulation regions comprises a cylindrical structure in cross section with respect to the connection surface of the electrically conductive electrode material.

6. The connection electrode of claim 1, wherein at least one of the plurality of insulation regions comprises SiO₂ and the electrically conductive electrode material comprises TiN.

7. A phase change memory element, comprising:
a carrier layer;
a connection element electrically connected to the carrier layer;
a connection electrode comprising a connection surface and a main surface opposite to the connection surface, the main surface electrically connected to the connection element;
a phase change material formed at the connection surface; and
a connection counterelectrode formed on the phase change material, the connection counterelectrode formed on an opposite side of the phase change material than the connection electrode.

8. The phase change memory element of claim 7, wherein the connection element and the connection electrode are formed in a contact hole of a dielectric, and the phase change material is formed at a common surface of the dielectric and the connection electrode.

9. The phase change memory of claim 7, wherein the connection element, connection electrode, and phase change material are formed in a contact hole of a dielectric, and the connection counterelectrode is formed at a common surface of the dielectric and the phase change material.

10. A method for producing a phase change memory element, comprising:
a) forming a dielectric on a carrier layer;
b) forming an opening in the dielectric as far as the carrier layer;
c) forming a connection element in the opening;
d) forming a recess in a region of the connection element;
e) filling the recess with an auxiliary dielectric;
f) forming a plurality of masking elements at least at a surface of the auxiliary dielectric;
g) anisotropically etching back the regions of the auxiliary dielectric which are not covered by the masking elements as far as the connection element, to form a plurality of insulation regions;
h) filling the regions which lie between the insulation regions with an electrode material to form a connection electrode;
i) forming a phase change material at least at a surface of the connection electrode; and
j) forming a connection counterelectrode at an opposite main surface of the phase change material.

11. The method of claim 10, wherein step a) comprises:
depositing a first insulation layer on the carrier layer; and
depositing a second insulation layer on the first insulation layer;
wherein the carrier layer comprises an Si substrate, the first insulation layer comprises SiO₂, and the second insulation layer comprises Si₃N₄.

12. The method of claim 10, wherein step b) comprises:
forming a contact hole as the opening using a lithographic process.

13. The method of claim 10, wherein step c) comprises:
depositing an electrically conductive liner on a surface of the opening;
annealing the electrically conductive liner; and
depositing an electrically conductive filing layer on the electrically conductive liner;
wherein the electrically conductive liner comprises Ti/TiN.

14. The method of claim 10, wherein step d) comprise:
etching back the connection element to the opening.

15. The method of claim 10, wherein step e) comprises:
depositing SiO₂ over the surface of the phase change memory element; and
planarizing the surface of the phase change memory element.

16. The method of claim 10, wherein in step f), the plurality of masking element are formed sublithographically.

17. The method of claim 16, further comprising:
depositing nanocrystals over the surface of the phase change memory element using a LPCVC process.

18. The method of claim 17, wherein the nanocrystals are Si nanocrystals.

19. The method of claim 16, further comprising:
depositing HSG grains over the surface of the phase change memory element.

20. The method of claim 10, wherein step h) comprises:
depositing the electrode material conformally over the surface of the phase change memory element using an ALD process; and
removing the electrode material from a common surface of the dielectric and the plurality of insulation regions;
wherein the electrode material comprises TiN.

21. The method of claim 10, wherein step i) comprises:
depositing the phase change material over the surface of the phase change memory element;
wherein the phase change material comprises GeₓSb_{y}Te_{z}.

22. The method of claim 10, wherein step i) comprises:
etching the connection electrode to a predetermined depth; and
depositing the phase change material over the surface of the phase change memory element;
wherein the phase change material comprises GeₓSb_{y}Te_{z}.

23. The method of claim 10, wherein step j) comprises:
depositing the connection electrode over the surface of the of the phase change memory element;
wherein the connection counterelectrode comprises TiN.

24. An apparatus for producing a phase change memory element, comprising:
means for forming a dielectric on a carrier layer;
means for forming an opening in the dielectric as far as the carrier layer;
means for forming a connection element in the opening;
means for forming a recess in a region of the connection element;
means for filling the recess with an auxiliary dielectric;
means for forming a plurality of masking elements at least at a surface of the auxiliary dielectric;
means for anisotropically etching back the regions of the auxiliary dielectric which are not covered by the masking elements as far as the connection element, to form a plurality of insulation regions;
means for filling the regions which lie between the insulation regions with an electrode material to form a connection electrode;
means for forming a phase change material at least at a surface of the connection electrode; and
means for forming a connection counterelectrode at an opposite main surface of the phase change material.

25. A phase change memory element, comprising:
a carrier layer;
a connection element electrically connected to the carrier layer;
a connection electrode comprising:
an electrically conductive electrode material comprising a connection surface;
a main surface opposite to the connection surface; and
a plurality of insulation regions formed within the electrically conductive electrode material;
wherein at least a portion of the plurality of insulation regions are formed at least partially at the connection surface of the electrically conductive electrode material to reduce an overall size of the connection surface;
a phase change material formed at the connection surface; and
a connection counterelectrode formed on the phase change material, the connection counterelectrode formed on an opposite side of the phase change material than the connection electrode.
